(19) United States
(12) Patent Application Publication
(10) Pub. No.: US 2025/0374757 A1
(43) Pub. Date: Dec. 4, 2025

(54) APPARATUS FOR MANUFACTURING DISPLAY DEVICE

(71) Applicant: Samsung Display Co., Ltd., Yongin-si (KR)

(72) Inventors: Jinhong Jeun, Yongin-si (KR); Jeonghun Woo, Yongin-si (KR); Doowon Lee, Yongin-si (KR); Haesook Lee, Yongin-si (KR); Jekil Ryu, Yongin-si (KR)

(73) Assignee: Samsung Display Co., Ltd., Yongin-si (KR)

(21) Appl. No.: 19/078,896

(22) Filed: Mar. 13, 2025

(30) Foreign Application Priority Data
May 28, 2024 (KR) 10-2024-0069524

(51) Int. Cl. H10K 59/12; H10K 71/20

(52) U.S. Cl. CPC H10K 59/1201; H10K 71/211

(57) ABSTRACT

Provided is an apparatus for manufacturing a display device, the apparatus cutting a mother substrate along a cutting line, wherein the mother substrate includes a first substrate, a second substrate disposed on the first substrate, and a plurality of display portions and a plurality of pad portions, which are arranged between the first substrate and the second substrate.

### CROSS REFERENCE TO RELATED APPLICATION

This application claims priority to and benefits of Korean Patent Application No. 10-2024-0069524 under 35 U.S.C. § 119, filed on May 28, 2024, in the Korean Intellectual Property Office, the entire contends of which are incorporated herein by reference.

### BACKGROUND

### 1. Technical Field

One or more embodiments relate to an apparatus, and more particularly, to an apparatus for manufacturing a display device.

### 2. Description of the Related Art

Mobility-based electronic devices are widely used. In addition to small electronic devices such as mobile phones, tablet personal computers (PC) have been widely used in recent years as mobile electronic devices.

A mobile electronic device includes a display device that provides visual information, such as an image or a video, to a user and supports various functions. Recently, as the size of other components for driving a display device has been reduced, the proportion of the display device in an electronic device has gradually increased, and a structure that may be bent by a certain angle from a flat state has been developed.

### SUMMARY

One or more embodiments include an apparatus that attaches a first substrate to a second substrate and then cuts the first substrate and the second substrate without damaging a pad portion.

However, embodiments are not limited to those set forth herein. The above and other embodiments will become more apparent to one of ordinary skill in the art to which the disclosure pertains by referencing the detailed description of the disclosure given below.

According to one or more embodiments, an apparatus for manufacturing a display device, which cuts a mother substrate along a cutting line, wherein the mother substrate includes a first substrate, a second substrate disposed on the first substrate, and a plurality of display portions and a plurality of pad portions, which are arranged between the first substrate and the second substrate, includes an optical device, and a controller that controls the optical device, wherein the optical device includes a stage on which the mother substrate is mounted, a first laser part disposed on the stage and that emits a first laser beam cutting the first substrate, a second laser part disposed on the stage and that emits a second laser beam cutting the second substrate, and a moving part that moves each of the first laser part and the second laser part, wherein the controller controls the optical device according to a first state, a second state, and a third state, wherein, in the first state, the first laser part emits the first laser beam and the second laser part emits the second laser beam, in the second state, the second laser part emits the second laser beam and the first laser part emits the first laser beam, and, in the third state, the first laser part emits the first laser beam and the second laser part does not emit the second laser beam.

In an embodiment, the mother substrate may be divided into a plurality of cells arranged in a first direction and a second direction intersecting the first direction, each of the plurality of cells may include a display portion and a pad portion, and the cutting line may include a first line extending in the first direction and arranged between two adjacent cells, a second line extending in the second direction and arranged between two adjacent cells, and a third line extending in the first direction and arranged between a protection portion and the pad portion of a cell.

In an embodiment, the controller may control the optical device so that the first laser part and the second laser part may cut the mother substrate along the first line and the second line in the first state.

In an embodiment, the controller may control the optical device so that the second laser part may cut the mother substrate along the third line in the second state.

In an embodiment, the controller may control the optical device so that the first laser part may cut the mother substrate along the first line and the second line in the third state.

In an embodiment, the controller may control the optical device so that the second laser part may sequentially cut the mother substrate along the third line, the first line, and the second line in the second state.

In an embodiment, the moving part may include a first moving part that moves each of the first laser part and the second laser part in a first direction, a second moving part that moves each of the first laser part and the second laser part in a second direction intersecting the first direction, a third moving part that moves the first laser part in a third direction intersecting the first direction and the second direction, and a fourth moving part that moves the second laser part in the third direction.

In an embodiment, the controller may control the third moving part and the fourth moving part so that the first laser part and the second laser part may independently move in the third direction.

In an embodiment, the first laser beam may have a wavelength in a range of about 1.3 μm to about 2.5 μm and a pulse width in a range of about 1 ns to about 200 ns.

In an embodiment, the second laser beam may have a wavelength in a range of about 1.0 μm to about 2.5 μm and a pulse width in a range of about 300 fs to about 30 ps.

According to one or more embodiments, an apparatus for manufacturing a display device, which cuts a mother substrate along a cutting line, wherein the mother substrate includes a first substrate, a second substrate disposed on the first substrate, and a plurality of display portions and a plurality of pad portions, which are arranged between the first substrate and the second substrate, includes a stage on which the mother substrate is mounted, a first laser part disposed on the stage and that emits a first laser beam cutting the first substrate, a second laser part disposed on the stage and that emits a second laser beam cutting the second substrate, and a moving part that moves each of the first laser part and the second laser part, wherein the apparatus is operated according to a first state, a second state, and a third state, wherein, in the first state, the first laser part emits the first laser beam and the second laser part emits the second laser beam, in the second state, the second laser part emits the second laser beam and the first laser part emits the first laser beam, and, in the third state, the first laser part emits the first laser beam and the second laser part does not emit the second laser beam.

In an embodiment, the mother substrate may be divided into a plurality of cells arranged in a first direction and a second direction intersecting the first direction, each of the plurality of cells may include a display portion and a pad portion, and the cutting line may include a first line extending in the first direction and arranged between two adjacent cells, a second line extending in the second direction and arranged between two adjacent cells, and a third line extending in the first direction and arranged between a protection portion and the pad portion of a cell.

In an embodiment, in the first state, the first laser part and the second laser part may cut the mother substrate along the first line and the second line.

In an embodiment, in the second state, the second laser part may cut the mother substrate along the third line.

In an embodiment, in the third state, the first laser part may cut the mother substrate along the first line and the second line.

In an embodiment, in the second state, the second laser part may sequentially cut the mother substrate along the third line, the first line, and the second line.

In an embodiment, the moving part may include a first moving part that moves each of the first laser part and the second laser part in a first direction, a second moving part that moves each of the first laser part and the second laser part in a second direction intersecting the first direction, a third moving part that moves the first laser part in a third direction intersecting the first direction and the second direction, and a fourth moving part that moves the second laser part in the third direction.

In an embodiment, the first laser part and the second laser part may be moved independently in the third direction.

In an embodiment, the first laser beam may have a wavelength a range of about 1.3 μm to about 2.5 μm and a pulse width a range of about 1 ns to about 200 ns.

In an embodiment, the second laser beam may have a wavelength a range of about 1.0 μm to about 2.5 μm and a pulse width a range of about 300 fs to about 30 ps.

Other aspects, features, and advantages other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a mother substrate according to an embodiment;

FIG. 2 is a schematic cross-sectional view of a mother substrate according to an embodiment;

FIG. 3 is a schematic cross-sectional view of a mother substrate according to an embodiment;

FIG. 4 is a schematic plan view of a display device according to an embodiment;

FIG. 5 is a schematic diagram of an equivalent circuit of a pixel circuit included in a display device according to an embodiment;

FIG. 6 is a schematic cross-sectional view of a display device according to an embodiment;

FIG. 7 is a schematic plan view of a display device according to an embodiment;

FIG. 8 is a schematic perspective view of an apparatus for manufacturing a display device according to an embodiment;

FIGS. 9A, 9B, and 9C are schematic cross-sectional views each illustrating a display device according to an embodiment;

FIGS. 10A, 10B, and 10C are schematic cross-sectional views each illustrating a display device according to an embodiment;

FIGS. 11A, 11B, and 11C are schematic cross-sectional views each illustrating a display device according to an embodiment;

FIGS. 12A, 12B, and 12C are schematic plan views each illustrating a mother substrate according to an embodiment;

FIGS. 12D and 12E are schematic cross-sectional views each illustrating a display device according to an embodiment;

FIG. 13A is a schematic plan view of a mother substrate according to an embodiment;

FIGS. 13B, 13C, 13D, 13E, and 13F are schematic cross-sectional views each illustrating a display device according to an embodiment; and

FIG. 13G is a schematic plan view of a mother substrate according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. For example, for example, intervening layers, regions, or elements may be present.

Sizes of elements in the drawings may be exaggerated for convenience of explanation. In other words, since sizes and thicknesses of components in the drawings are arbitrarily illustrated for convenience of explanation, the following embodiments are not limited thereto.

The x-axis, the y-axis, and the z-axis are not limited to three axes on the orthogonal coordinates system, and may be interpreted in a broad sense including the same. For example, the x-axis, the y-axis, and the z-axis may be perpendicular to one another, or may represent different directions that are not perpendicular to one another.

In case that a certain embodiment may be implemented differently, a specific process order may be performed differently from the described order. For example, two consecutively described processes may be performed substantially at the same time or performed in an order opposite to the described order.

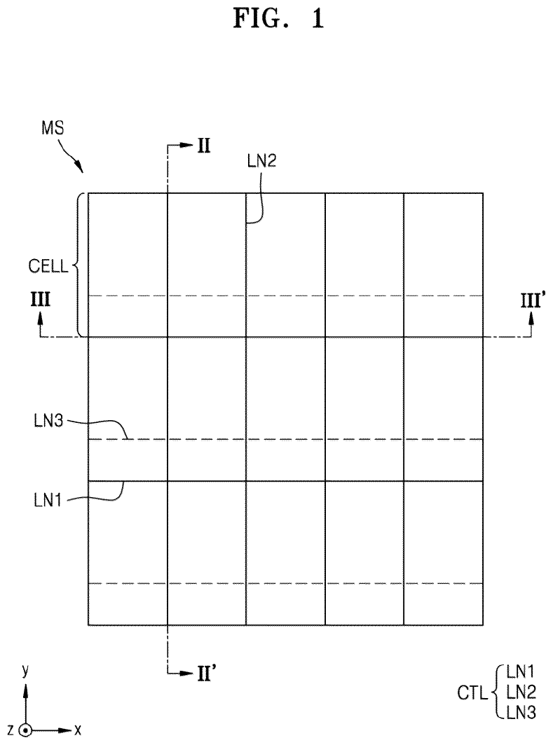

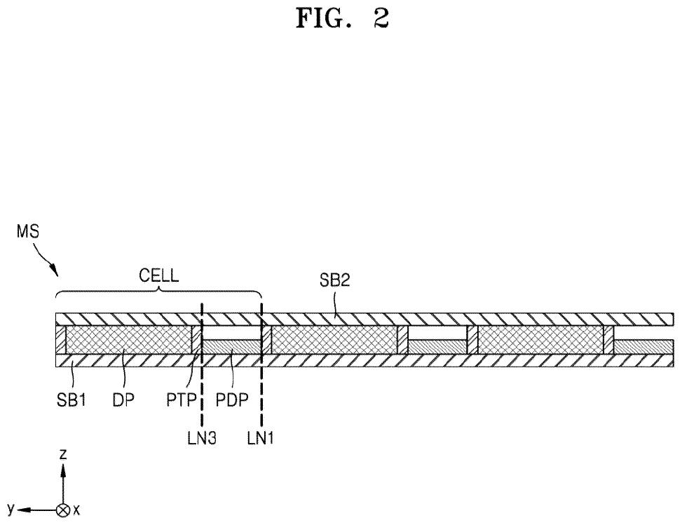

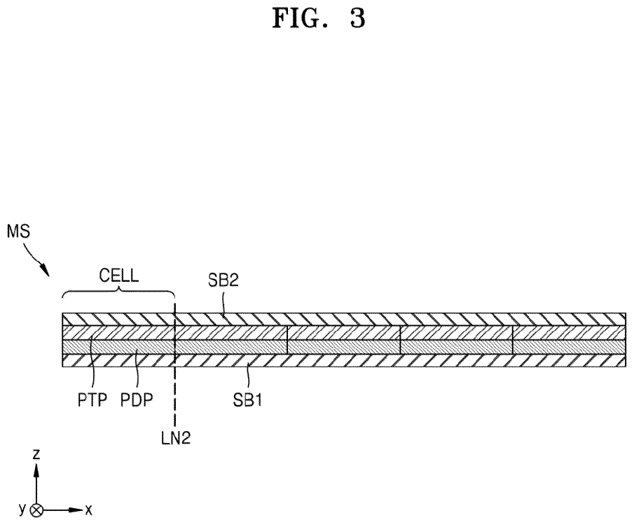

FIG. 1 is a schematic plan view of a mother substrate MS according to an embodiment, FIG. 2 is a schematic cross-sectional view of the mother substrate MS according to an embodiment, and FIG. 3 is a schematic cross-sectional view of the mother substrate MS according to an embodiment.

FIG. 2 is a cross-sectional view taken along line II-II′ of FIG. 1, and FIG. 3 is a cross-sectional view taken along line III-III′ of FIG. 1.

Referring to FIGS. 1 to 3, the mother substrate MS may include a first substrate SB1, a display portion DP, a protection portion PTP, a pad portion PDP, and a second substrate SB2.

Display portions DP, protection portions PTP, and pad portions PDP may be provided. Each of the display portions DP, the protection portions PTP, and the pad portions PDP may be disposed on the first substrate SB1. The second substrate SB2 may be disposed on the display portions DP, the protection portions PTP, and the pad portions PDP. For example, the second substrate SB2 may be disposed above the first substrate SB1, and the display portions DP, the protection portions PTP, and the pad portions PDP may be arranged between the first substrate SB1 and the second substrate SB2.

The display portions DP may be in contact with each of the first substrate SB1 and the second substrate SB2. The protection portions PTP may be in contact with each of the first substrate SB1 and the second substrate SB2. The pad portions PDP may be in contact with the first substrate SB1 but may be spaced apart from the second substrate SB2 in the third direction (e.g., in the z-axis direction).

For example, the protection portion PTP may include at least one material from among polyacrylates resin, epoxy resin, phenolic resin, polyamides resin, polyimides resin, unsaturated polyesters resin, poly phenylenethers resin, and poly phenylenesulfides resin. However, this is an example, and the material of the protection portion PTP is not limited thereto.

The mother substrate MS may be divided into cells CELL arranged in a first direction (e.g., an x-axis direction) and a second direction (e.g., a y-axis direction). The second direction (e.g., the y-axis direction) may be a direction intersecting the first direction (e.g., the x-axis direction). For example, an angle between the first direction (e.g., the x-axis direction) and the second direction (e.g., the y-axis direction) may be 90 degrees. In such a structure, the cells CELL may be arranged in a grid shape.

Each of the cells CELL may include a display portion (e.g., single display portion) DP and a pad portion (e.g., single pad portion) PDP. For example, the display portion DP and the pad portion PDP arranged in a cell (e.g., single cell) CELL may be arranged in the second direction (e.g., the y-axis direction). The display portion DP and the pad portion PDP may be electrically connected to each other. The protection portion PTP may be disposed on a side surface of the display portion DP to protect the display portion DP. The protection portion PTP may be disposed on the side surface of the display portion DP in the second direction (e.g., the y-axis direction). The protection portion PTP and the display portion DP may be in contact with each other.

In the mother substrate MS, the first substrate SB1 and the second substrate SB2 may be integrally provided. For example, the cells CELL may share a first substrate SB1 and a second substrate SB2. Accordingly, the mother substrate MS may be cut along a cutting line CTL by an apparatus MD for manufacturing a display device, which will be described below. For example, each of the first substrate SB1 and the second substrate SB2 may be cut into substrates along the cutting line CTL.

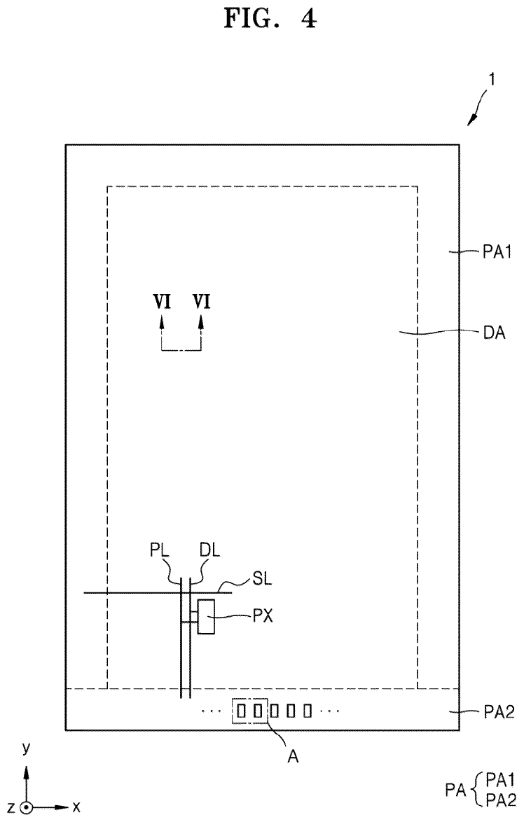

As the mother substrate MS is cut along the cutting line CTL, display devices 1 (refer to FIG. 4) may be manufactured. The cells CELL included in the mother substrate MS may form the display devices 1. For example, a cell (e.g., single cell) CELL may correspond to a display device (e.g., single display device) 1.

The cutting line CTL may include a first line LN1, a second line LN2, and a third line LN3. The first line LN1 may extend in the first direction (e.g., the x-axis direction) and may be arranged between two adjacent cells CELL. The first line LN1 may be arranged at a boundary between two adjacent cells CELL arranged in the second direction (e.g., the y-axis direction). The second line LN2 may extend in the second direction (e.g., the y-axis direction) and may be arranged between two adjacent cells CELL. The second line LN2 may be arranged at a boundary between two adjacent cells CELL arranged in the first direction (e.g., the x-axis direction). The third line LN3 may extend in the first direction (e.g., the x-axis direction) and may be arranged between the protection portion PTP and the pad portion PDP of a cell (e.g., single cell) CELL. The third line LN3 may be arranged at a boundary between the protection portion PTP and the pad portion PDP in a cell (e.g., single cell) CELL. For example, first lines LN1, second lines LN2, and third lines LN3 may be provided.

FIG. 4 is a schematic plan view of the display device 1 according to an embodiment.

Referring to FIG. 4, the display device 1 may include a display area DA and a peripheral area PA outside the display area DA. In FIG. 4, the display area DA is shown as having a rectangular shape. However, embodiments are not limited thereto. The display area DA may have various shapes, for example, a circular shape, an oval shape, a polygonal shape, a shape of a particular figure, or the like.

The display area DA may be a portion that displays an image, and pixels PX may be arranged in the display area DA. Each pixel PX may include a display element such as an organic light-emitting diode. Each pixel PX may emit, for example, red light, green light, or blue light. Such a pixel PX may be connected to a pixel circuit including a thin-film transistor (TFT), a storage capacitor, or the like. Such a pixel circuit may be electrically connected to a scan line SL that transmits a scan signal, a data line DL that intersects the scan line SL and transmits a data signal, a driving voltage line PL that supplies a driving voltage, or the like. The scan line SL may extend in the first direction (e.g., the x-axis direction), and the data line DL and the driving voltage line PL may extend in the second direction (e.g., the y-axis direction).

The pixel PX may emit light having brightness corresponding to an electrical signal from a pixel circuit electrically connected to the pixel PX. The display area DA may display a certain image through light emitted by the pixel PX. For reference, the pixel PX may be defined as an emission area emitting any one of red light, green light, and blue light, as described above.

The peripheral area PA may be an area in which the pixel PX is not arranged and may be an area that does not display an image. The peripheral area PA may include a first peripheral area PA1 and a second peripheral area PA2. A power supply line for driving the pixel PX or the like may be positioned in the first peripheral area PA1. The pad portion PDP or the like that is electrically connected to a printed circuit board including a driving circuit part or an electronic chip package including an integrated circuit (IC) chip may be arranged in the second peripheral area PA2.

Hereinafter, the display device 1 according to an embodiment is described as an organic light-emitting display device as an example. However, the display device 1 of the disclosure is not limited thereto. For example, the display device 1 may also be an inorganic light-emitting display device (or inorganic electroluminescent (EL) display device) or a quantum dot light-emitting display device. For example, an emission layer of a display element included in the display device 1 may include an organic material or an inorganic material. For example, the display device 1 may also include an emission layer and a quantum dot layer positioned on a path of light emitted by the emission layer.

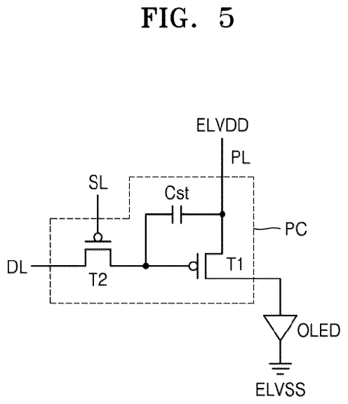

FIG. 5 is a schematic diagram of an equivalent circuit of a pixel circuit PC included in the display device 1 according to an embodiment. The pixel circuit PC may be electrically connected to a display element, and a display element (e.g., single element) may correspond to a pixel (e.g., single pixel) PX. For example, the display element may be an organic light-emitting diode OLED.

The pixel circuit PC may include a first transistor T1, a second transistor T2, and a storage capacitor Cst. The second transistor T2 may be a switching transistor, which is connected to the scan line SL and the data line DL and turned on by a switching signal input from the scan line SL to transmit, to the first transistor T1, a data signal input from the data line DL. The storage capacitor Cst may have an end electrically connected to the second transistor T2 and another end electrically connected to the driving voltage line PL, and may store a voltage corresponding to the difference between a voltage received from the second transistor T2 and a driving power voltage ELVDD supplied to the driving voltage line PL.

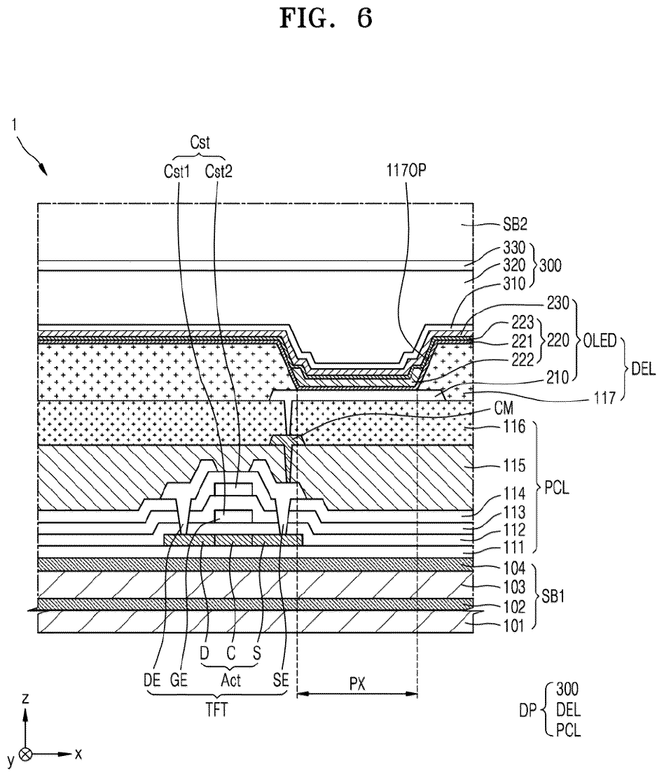

The first transistor T1 may be a driving transistor, which is connected to the driving voltage line PL and the storage capacitor Cst and controls a driving current flowing through the organic light-emitting diode OLED from the driving voltage line PL, in accordance with a voltage value stored in the storage capacitor Cst. The organic light-emitting diode OLED may emit light having a certain brightness according to the driving current. An opposite electrode 230 (refer to FIG. 6) of the organic light-emitting diode OLED may receive an electrode power voltage ELVSS.

FIG. 5 illustrates that the pixel circuit PC includes two transistors and one storage capacitor, but embodiments are not limited thereto. For example, the number of transistors or the number of storage capacitors may be variously changed according to the design of the pixel circuit PC.

FIG. 6 is a schematic plan view of the display device 1 according to an embodiment.

FIG. 6 is a cross-sectional view taken along line VI-VI′ of FIG. 4. For example, FIG. 6 is a cross-sectional view of the display area DA (refer to FIG. 4) of the display device 1.

Referring to FIGS. 4 and 6, the display device 1 may include the first substrate SB1, the display portion DP, and the second substrate SB2 in the display area DA. For example, the display portion DP may include a stacked structure of a pixel circuit layer PCL, a display element layer DEL, and an encapsulation layer 300.

The first substrate SB1 may have a multi-layered structure including a base layer and an inorganic layer, the base layer including a polymer resin. For example, the first substrate SB1 may include the base layer including the polymer resin, and a barrier layer of an inorganic insulating layer. For example, the first substrate SB1 may include a first base layer 101, a first barrier layer 102, a second base layer 103, and a second barrier layer 104, which are sequentially stacked. Each of the first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC), or/and cellulose acetate propionate (CAP), or the like. The first barrier layer 102 and the second barrier layer 104 may each include an inorganic insulating material, such as silicon oxide, silicon nitride, and/or silicon oxynitride. The first substrate SB1 may be flexible.

The pixel circuit layer PCL may be disposed on the first substrate SB1. FIG. 6 illustrates that the pixel circuit layer PCL includes a thin-film transistor TFT, a buffer layer 111, a first gate insulating layer 112, a second gate insulating layer 113, an interlayer insulating layer 114, a first planarization insulating layer 115, and a second planarization insulating layer 116, wherein the buffer layer 111, the first gate insulating layer 112, the second gate insulating layer 113, the interlayer insulating layer 114, the first planarization insulating layer 115, and the second planarization insulating layer 116 are disposed below or/and above components of the thin-film transistor TFT.

The buffer layer 111 may reduce or block penetration of foreign materials, moisture, or external air from a portion of the first substrate SB1 and may provide a flat surface on the first substrate SB1. The buffer layer 111 may include an inorganic insulating material, such as silicon oxide, silicon oxynitride, and silicon nitride, and may include a single-layered structure or a multi-layered structure, each including the material stated above.

The thin-film transistor TFT disposed on the buffer layer 111 may include a semiconductor layer Act, and the semiconductor layer Act may include polysilicon (poly-Si). In another example, the semiconductor layer Act may include amorphous silicon (a-Si), an oxide semiconductor, an organic semiconductor, or the like. The semiconductor layer Act may include a channel area C, a drain area D, and a source area S. For example, the drain area D and the source area S may be respectively arranged on sides (e.g., opposite sides) of the channel area C. A gate electrode GE of the thin-film transistor TFT may overlap the channel area C.

The gate electrode GE may include a low-resistance metal material. The gate electrode GE may include a conductive material including molybdenum (Mo), aluminum (Al), copper (Cu), titanium (Ti), or the like, and may be a multi-layer or a single layer, each including the material stated above.

The first gate insulating layer 112 between the semiconductor layer Act and the gate electrode GE may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnOₓ), or the like. For example, the zinc oxide (ZnOₓ) may be zinc oxide (ZnO) and/or zinc peroxide (ZnO₂).

The second gate insulating layer 113 may cover the gate electrode GE. Similar to the first gate insulating layer 112, the second gate insulating layer 113 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnOₓ), or the like. The zinc oxide (ZnOₓ) may be zinc oxide (ZnO) and/or zinc peroxide (ZnO₂).

An upper electrode Cst2 of a storage capacitor Cst may be disposed on the second gate insulating layer 113. The upper electrode Cst2 may overlap the gate electrode GE therebelow. For example, the gate electrode GE and the upper electrode Cst2, which overlap each other with the second gate insulating layer 113 therebetween, may form the storage capacitor Cst. For example, the gate electrode GE may function as a lower electrode Cst1 of the storage capacitor Cst.

As such, the storage capacitor Cst and the thin-film transistor TFT may overlap each other. In some embodiments, the storage capacitor Cst may not overlap the thin-film transistor TFT.

The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be a single layer or a multi-layer, each including the material stated above.

The interlayer insulating layer 114 may cover the upper electrode Cst2. The interlayer insulating layer 114 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnOₓ), or the like. The zinc oxide (ZnOₓ) may be zinc oxide (ZnO) and/or zinc peroxide (ZnO₂). The interlayer insulating layer 114 may include a single layer or a multi-layer, each including the inorganic insulating material stated above.

Each of a drain electrode DE and a source electrode SE of the thin-film transistor TFT may be disposed on the interlayer insulating layer 114. The drain electrode DE and the source electrode SE may respectively be connected to the drain area D and the source area S through contact holes formed in insulating layers below the drain electrode DE and the source electrode SE. The drain electrode DE and the source electrode SE may each include a material having good conductivity. The drain electrode DE and the source electrode SE may each include a conductive material including Mo, Al, Cu, Ti, or the like, and may include a multi-layer or a single layer, each including the above material. In an embodiment, the drain electrode DE and the source electrode SE may each have a multi-layered structure of Ti/Al/Ti.

The first planarization insulating layer 115 may cover the drain electrode DE and the source electrode SE. The first planarization insulating layer 115 may include a general commercial polymer, such as poly (methyl methacrylate) (PMMA) or polystyrene (PS), a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, and a mixture thereof.

The second planarization insulating layer 116 may be disposed on the first planarization insulating layer 115. The second planarization insulating layer 116 may include the same material as the first planarization insulating layer 115, and may include a general commercial polymer, such as PMMA or PS, a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, and a mixture thereof.

The display element layer DEL may be disposed on the pixel circuit layer PCL having the structure described above. The display element layer DEL may include an organic light-emitting diode OLED as a display element (e.g., a light-emitting element), and the organic light-emitting diode OLED may include a stacked structure of a pixel electrode 210, an intermediate layer 220, and a common electrode 230. The organic light-emitting diode OLED may emit, for example, red light, green light, or blue light, or may emit red light, green light, blue light, or white light. The organic light-emitting diode OLED may emit light through an emission area, and define the emission area as a pixel PX.

The pixel electrode 210 of the organic light-emitting diode OLED may be electrically connected to the thin-film transistor TFT through contact holes formed in the second planarization insulating layer 116 and the first planarization insulating layer 115 and a contact metal CM disposed on the first planarization insulating layer 115.

The pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective film including Ag, Mg, Al, Pt, Pd, Au, Ni, Nd, Ir, Cr, or a compound thereof. In another embodiment, the pixel electrode 210 may further include a film including ITO, IZO, ZnO, or In₂O₃ above/below the reflective film described above.

A bank layer 117 having an opening 117OP exposing the central portion of the pixel electrode 210 may be disposed on the pixel electrode 210. The bank layer 117 may include an organic insulating material and/or an inorganic insulating material. The opening 117OP may define (or correspond to) an emission area of light emitted from the organic light-emitting diode OLED. For example, the size/width of the opening 117OP may correspond to the size/width of the emission area. Accordingly, the size and/or width of the pixel PX may depend on the size and/or width of the opening 117OP of the bank layer 117.

The intermediate layer 220 may include an emission layer 222 formed to correspond to the pixel electrode 210. The emission layer 222 may include a polymer organic material or a low-molecular-weight organic material, which emits light of a certain color. In another example, the emission layer 222 may include an inorganic light-emitting material or a quantum dot.

In an embodiment, the intermediate layer 220 may include a first functional layer 221 and a second functional layer 223 respectively disposed below and on the emission layer 222. The first functional layer 221 may include, for example, a hole transport layer (HTL), or an HTL and a hole injection layer (HIL). The second functional layer 223 may be a component disposed on the emission layer 222, and may include an electron transport layer ETL and/or an electron injection layer (EIL). Similar to the common electrode 230 to be described below, the first functional layer 221 and/or the second functional layer 223 may be a common layer formed to cover (e.g., entirely cover) the first substrate SB1.

The common electrode 230 may be disposed above the pixel electrode 210 and overlap the pixel electrode 210. The common electrode 230 may include a conductive material having a low work function. For example, the common electrode 230 may include a transparent layer or a semi-transparent layer including Ag, Mg, Al, Pt, Pd, Au, Ni, Nd, Ir, Cr, lithium (Li), Ca, an alloy thereof, or the like. In another example, the common electrode 230 may further include a layer, such as ITO, IZO, ZnO, or In₂O₃, above the transparent layer or the semi-transparent layer including the materials stated above. The common electrode 230 may be integrally formed to cover (e.g., entirely cover) the first substrate SB1.

The encapsulation layer 300 may be disposed on the display element layer DEL and cover (e.g., entirely cover) the display element layer DEL. The encapsulation layer 300 may include at least one inorganic encapsulation layer and at least one organic encapsulation layer, and in an embodiment, FIG. 6 shows that the encapsulation layer 300 includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acrylic resin, an epoxy resin, polyimide (PI), polyethylene, or the like. In an embodiment, the organic encapsulation layer 320 may include acrylate. The organic encapsulation layer 320 may be formed by curing a monomer or coating a polymer. The organic encapsulation layer 320 may have transparency.

The second substrate SB2 may be disposed on the display portion DP. For example, the second substrate SB2 may be disposed on the encapsulation layer 300. The second substrate SB2 may include a glass material. For example, the second substrate SB2 may include ultra-thin glass (UTG). However, this is an example, and the material of the second substrate SB2 is not limited thereto.

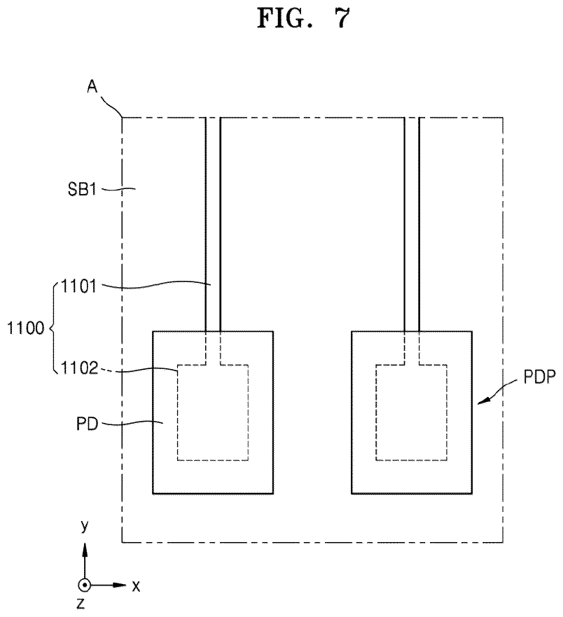

FIG. 7 is a schematic plan view of the display device 1 according to an embodiment.

FIG. 7 is an enlarged view of a region A of FIG. 4. For example, FIG. 7 is a cross-sectional view of the second peripheral area PA2 (refer to FIG. 4) of the display device 1.

Referring to FIGS. 4 and 7, the display device 1 may include the first substrate SB1 and the pad portion PDP in the second peripheral area PA2. For example, in the second peripheral area PA2, the second substrate SB2 may not be disposed on the pad portion PDP.

The pad portion PDP may be electrically connected to a signal line arranged in the display area DA. The pad portion PDP may include a connection line 1100 and a pad PD.

The pad PD may be arranged to overlap a portion of the connection line 1100. The connection lines 1100 may electrically connect signal lines arranged in the display area DA, for example, data lines, and pads PD to each other. Each of the connection lines 1100 may include a first portion 1101 extending in a direction and a second portion 1102 disposed on the end portion of the first portion 1101 to electrically connect a signal line to the pad PD.

The pad PD may be positioned on the upper portion of the second portion 1102 of the connection line 1100 to overlap the second portion 1102 of the connection line 1100. Accordingly, the pad PD may be electrically connected to a signal line arranged in the display area DA through the connection line 1100. However, embodiments are not limited thereto. For example, a signal line arranged in the display area DA may be disposed on the same layer as a layer where the pad PD is disposed to be electrically connected to the pad PD. For example, the display device 1 may not include the connection line 1100.

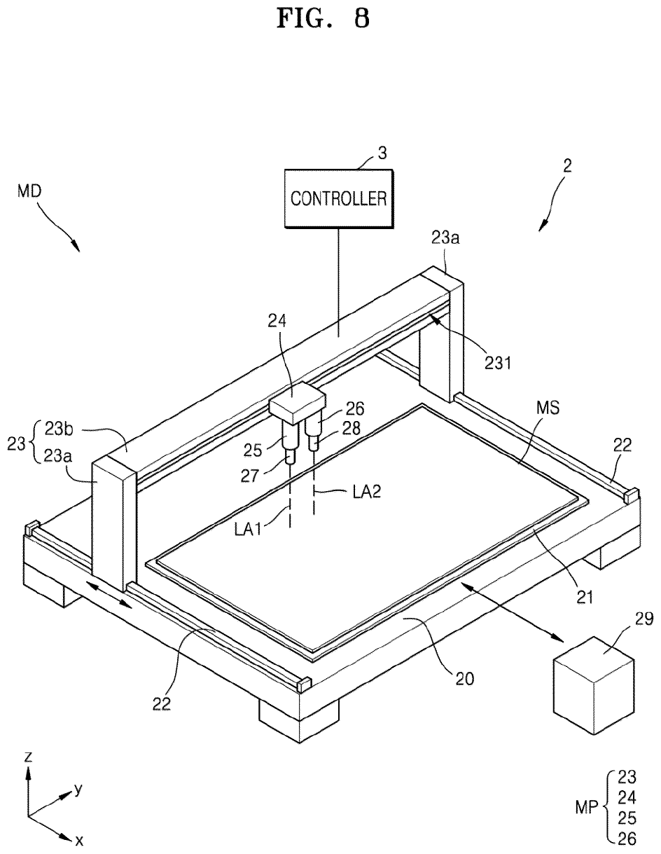

FIG. 8 is a schematic perspective view of an apparatus for manufacturing the display device 1 according to an embodiment.

Referring to FIGS. 1 to 3 and 8, an apparatus MD for manufacturing a display device may cut the mother substrate MS along the cutting line CTL. The apparatus MD for manufacturing a display device may include an optical device 2 and a controller 3.

The optical device 2 may include a support part 20, a stage 21, a guide part 22, a moving part MP, a first laser part 27, a second laser part 28, and an inversion part 29.

The support part 20 may support the stage 21, the guide part 22, the moving part MP, the first laser part 27, the second laser part 28, and the inversion part 29. The support part 20 may have a plane defined by the first direction (e.g., the x-axis direction) and the second direction (e.g., the y-axis direction).

The stage 21 may be disposed on the support part 20 and have a plane defined by the first direction (e.g., the x-axis direction) and the second direction (e.g., the y-axis direction). The mother substrate MS may be mounted on the stage 21.

The guide part 22 may be disposed on the support part 20 and may be arranged on each of sides (e.g., opposite sides) of the guide part 22 to be spaced apart from each other with the stage 21 therebetween. For example, two guide parts 22 may be provided and may be arranged to be spaced apart from each other in the second direction (e.g., the y-axis direction). Each of the guide parts 22 may extend in the first direction (e.g., the x-axis direction), and the extension length of the guide part 22 in the first direction (e.g., the x-axis direction) may be at least longer than the length of an edge of the mother substrate MS in the first direction (e.g., the x-axis direction).

The moving part MP may move each of the first laser part 27 and the second laser part 28 with respect to the stage 21. The moving part MP may move each of the first laser part 27 and the second laser part 28 in the first direction (e.g., the x-axis direction), the second direction (e.g., the y-axis direction), and a third direction (e.g., a z-axis direction). Here, the third direction (e.g., the z-axis direction) may be a direction intersecting the first direction (e.g., the x-axis direction) and the second direction (e.g., the y-axis direction). The moving part MP may include a first moving part 23, a second moving part 24, and a third moving part 25.

The first moving part 23 may move each of the first laser part 27 and the second laser part 28 in the first direction (e.g., the x-axis direction). The guide part 22 may guide the first moving part 23 so that the first moving part 23 may be able to perform linear movement in the extension direction of the guide parts 22. The guide parts 22 may include, for example, linear motion rails.

The first moving part 23 may linearly move back and forth in the first direction (e.g., the x-axis direction). The first moving part 23 may include a pillar member 23a and a horizontal member 23b. FIG. 8 shows that each of the pillar member 23a and the horizontal member 23b has a rectangular parallelepiped shape, but the shape of each of the pillar member 23a and the horizontal member 23b is not limited thereto.

The pillar member 23a of the first moving part 23 may extend in the third direction (e.g., the z-axis direction). For example, two pillar members 23a may be provided and may be disposed on sides (e.g., opposite sides) of the support part 20 with the stage 21 therebetween. The pillar members 23a may each move in the extension direction of the guide parts 22, e.g., the first direction (e.g., the x-axis direction). In an embodiment, the pillar members 23a may manually perform linear movement or may automatically perform linear movement by including a motor cylinder or the like. For example, the pillar members 23a may automatically perform linear movement by including a linear motion block that moves along a linear motion rail.

The horizontal member 23b of the first moving part 23 may extend between the pillar members 23a in the second direction (e.g., the y-axis direction). End portions (e.g., opposite end portions) of the horizontal member 23b may respectively be connected to upper portions of the pillar members 23a. The horizontal member 23b may include a first groove portion 231 that extends in the extension direction of the horizontal member 23b, e.g., the second direction (e.g., the y-axis direction). The first groove portion 231 may be arranged in a side surface of the horizontal member 23b. For example, the first groove portion 231 may be arranged in a side surface of the first moving part 23 among the side surfaces of the first moving part 23, the side surface facing the second direction (e.g., the y-axis direction). The first groove portion 231 may guide the second moving part 24 so that the second moving part 24 may be able to linearly move back and forth in the extension direction of the first groove portion 231.

The second moving part 24 may move each of the first laser part 27 and the second laser part 28 in the second direction (e.g., the y-axis direction). The second moving part 24 may linearly move in the second direction (e.g., the y-axis direction). The second moving part 24 may be movably connected to a side surface of the horizontal member 23b of the first moving part 23. For example, the second moving part 24 may be disposed on the side surface of the first moving part 23, on which the first groove portion 231 is disposed. The second moving part 24 may linearly move back and forth in the second direction (e.g., the y-axis direction) along the first groove portion 231. In an embodiment, the second moving part 24 may include a linear motor or the like.

The third moving part 25 may move the first laser part 27 in the third direction (e.g., the z-axis direction). The third moving part 25 may be disposed on a side of the second moving part 24 and may linearly move back and forth in the third direction (e.g., the z-axis direction). For example, the third moving part 25 may be disposed on the lower surface of the second moving part 24. For example, the lower surface of the second moving part 24 may be a surface where the second moving part 24 faces the stage 21.

A fourth moving part 26 may move the second laser part 28 in the third direction (e.g., the z-axis direction). The fourth moving part 26 may be disposed on a side of the second moving part 24 and may linearly move back and forth in the third direction (e.g., the z-axis direction). For example, the fourth moving part 26 may be disposed on the lower surface of the second moving part 24.

The third moving part 25 and the fourth moving part 26 may be arranged to be spaced apart from each other in the second direction (e.g., in the y-axis direction). The controller 3 may control the third moving part 25 and the fourth moving part 26 so that the first laser part 27 and the second laser part 28 may independently move in the third direction (e.g., the z-axis direction). The third moving part 25 and the fourth moving part 26 may operate independently from each other. Accordingly, the first laser part 27 and the second laser part 28 may independently move in the third direction (e.g., the z-axis direction). For example, each of the third moving part 25 and the fourth moving part 26 may include a pneumatic cylinder or the like.

The first laser part 27 may be disposed on the stage 21 and may emit a first laser beam LA1 to cut the first substrate SB1. The first laser part 27 may be connected to the moving part MP. For example, the first laser part 27 may be fixed to a side of the third moving part 25. Accordingly, the first laser part 27 may be moved in the first direction (e.g., the x-axis direction), the second direction (e.g., the y-axis direction), and the third direction (e.g., the z-axis direction) by the moving part MP.

The first laser beam LA1 may be emitted in the form of a laser beam. For example, the first laser beam LA1 may be a Bessel beam or a multi-focal beam. For example, the first laser part 27 may include at least one of an axicon lens, a spatial light modulator (SLM), and a diffractive optical element (DOE). For example, the first laser part 27 may include at least one of an auto focus part and a laser distance sensor (LDS). For example, the first laser beam LA1 may have a wavelength of about 1.3 μm or more and about 2.5 μm or less, and a pulse width of about 1 ns or more and about 200 ns or less. However, this is an example, and the configuration of the first laser part 27 and the properties of the first laser beam LA1 are not limited thereto.

The second laser part 28 may be disposed on the stage 21 and may emit a second laser beam LA2 to cut the second substrate SB2. The second laser part 28 may be connected to the moving part MP. For example, the second laser part 28 may be fixed to a side of the third moving part 25. Accordingly, the second laser part 28 may be moved in the first direction (e.g., the x-axis direction), the second direction (e.g., the y-axis direction), and the third direction (e.g., the z-axis direction) by the moving part MP.

The second laser beam LA2 may be emitted in the form of a laser beam. For example, the second laser beam LA2 may be a Bessel beam or a multi-focal beam. For example, the second laser part 28 may include at least one of an axicon lens, a spatial light modulator (SLM), and a diffractive optical element (DOE). For example, the second laser part 28 may include at least one of an auto focus part and a laser distance (LDS). For example, the second laser beam LA2 may have a wavelength of about 1.0 μm or more and about 2.5 μm or less, and a pulse width of about 300 fs or more and about 30 ps or less. However, this is an example, and the configuration of the second laser part 28 and the properties of the second laser beam LA2 are not limited thereto.

The inversion part 29 may invert the mother substrate MS. The inversion part 29 may flip the mother substrate MS so that the upper surface and the lower surface of the mother substrate MS may be swapped (or exchanged). For example, the inversion part 29 may include an inversion robot, and the inversion robot may invert the mother substrate MS by approaching the mother substrate MS. In another example, the inversion part 29 may also be in the form of an inversion device having a side fixed to a support or the stage 21. However, this is an example, and a method in which the inversion part 29 inverts the mother substrate MS is not limited thereto.

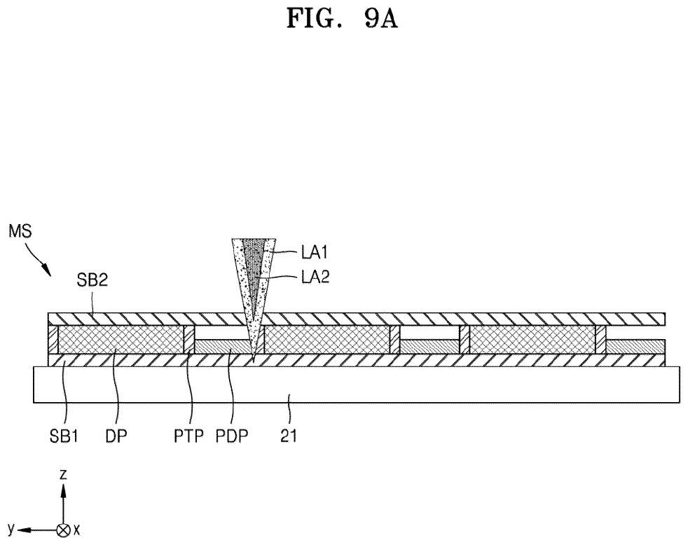

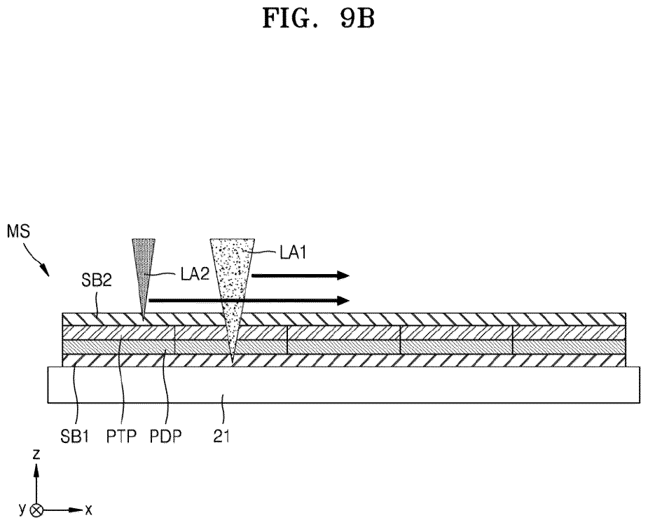

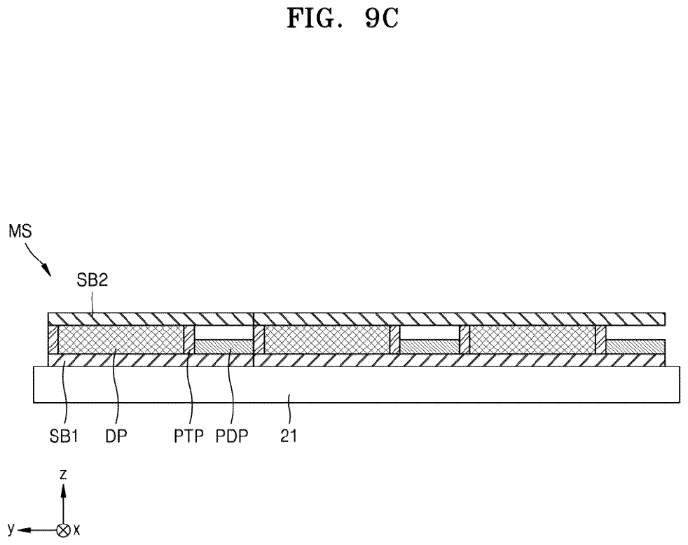

The controller 3 may control the optical device 2. For example, the controller 3 may control the moving part MP, the first laser part 27, the second laser part 28, and the inversion part 29. A detailed description of the controller 3 is made below with reference to FIGS. 9A to 13G.

FIGS. 9A to 9C are schematic cross-sectional views each illustrating the display device 1 according to an embodiment.

FIGS. 9A and 9C are cross-sectional views taken along line II-II′ of FIG. 1, and FIG. 9B is a cross-sectional view taken along line III-III′ of FIG. 1.

Referring to FIGS. 8 and 9A to 9C, a first state of the optical device 2 may be described.

In the first state, the controller 3 may control the optical device 2 so that the first laser part 27 may emit the first laser beam LA1 and the second laser part 28 may emit the second laser beam LA2. For example, in the first state, the first laser part 27 may emit the first laser beam LA1, and the second laser part 28 may emit the second laser beam LA2.

In the first state, the mother substrate MS may be mounted on the stage 21 so that the first substrate SB1 may be supported on the stage 21 and the second substrate SB2 may be spaced apart from the stage 21. For example, the first substrate SB1 may be disposed on the stage 21, the display portions DP, the protection portions PTP, and the pad portions PDP may be disposed on the first substrate SB1, and the second substrate SB2 may be disposed on the display portions DP, the protection portions PTP, and the pad portions PDP.

In the first state, the third moving part 25 may adjust the height of the first laser part 27 so that the focus of the first laser beam LA1 may be formed inside the first substrate SB1. For example, the fourth moving part 26 may adjust the height of the second laser part 28 so that the second laser beam LA2 may be formed inside the second substrate SB2.

In a state in which the height of each of the first laser part 27 and the second laser part 28 is adjusted, the first moving part 23 and/or the second moving part 24 may move the first laser part 27 and the second laser part 28 in the first direction (e.g., the x-axis direction) and/or the second direction (e.g., the y-axis direction), respectively.

For example, as shown in FIGS. 9A and 9B, the first moving part 23 may move each of the first laser part 27 and the second laser part 28 in the first direction (e.g., the x-axis direction). In such a process, as shown in FIG. 9C, each of the first substrate SB1 and the second substrate SB2 may be cut along the first direction (e.g., the x-axis direction).

However, as FIGS. 9A to 9C show an example of the first state of the optical device 2, the operation of the apparatus MD for manufacturing a display device is not limited thereto. For example, the second moving part 24 may move each of the first laser part 27 and the second laser part 28 in the second direction (e.g., the y-axis direction), and each of the first substrate SB1 and the second substrate SB2 may also be cut along the second direction (e.g., the y-axis direction).

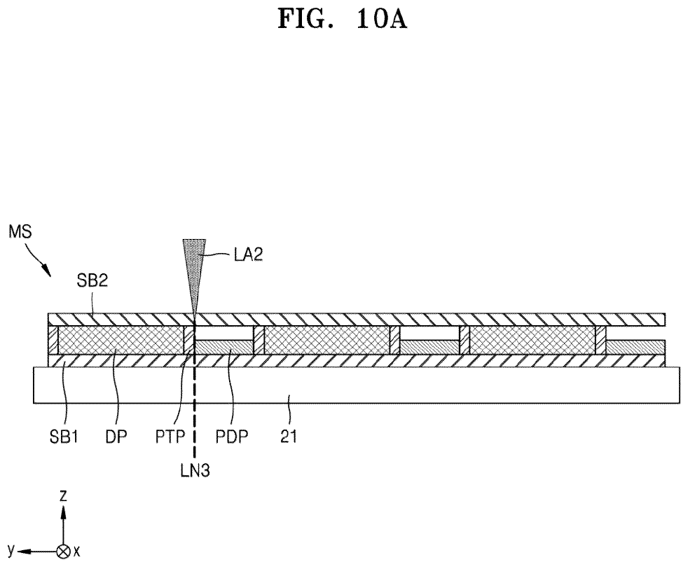

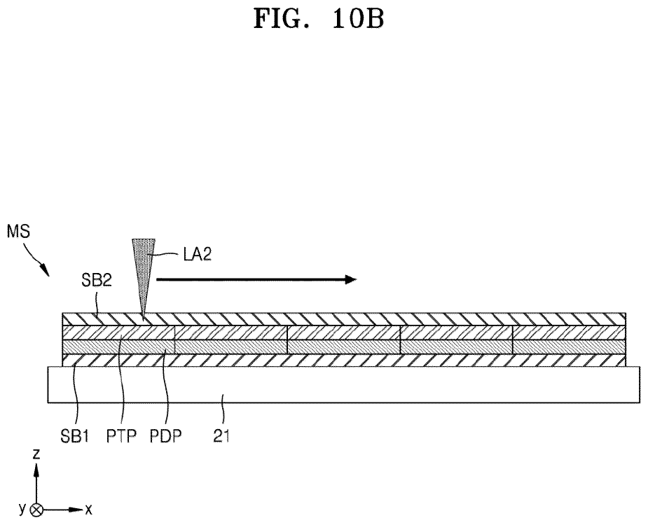

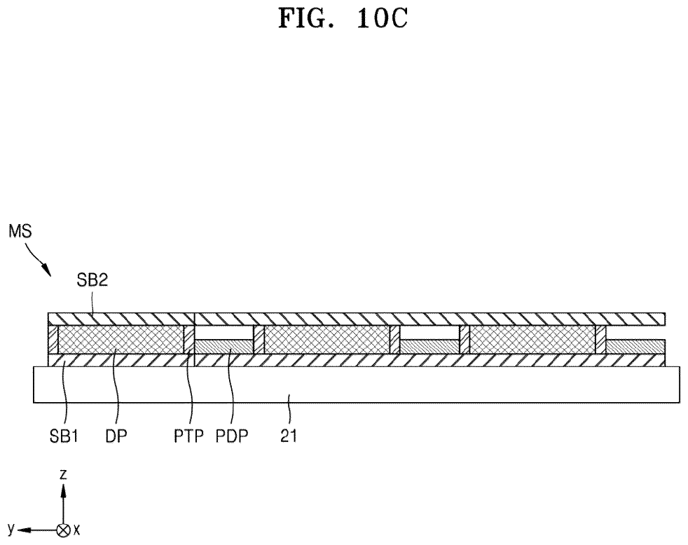

FIGS. 10A to 10C are schematic cross-sectional views each illustrating the display device 1 according to an embodiment.

FIGS. 10A and 10C are cross-sectional views taken along line II-II′ of FIG. 1, and FIG. 10B is a cross-sectional view taken along line III-III′ of FIG. 1.

Referring to FIGS. 8 and 10A to 10C, a second state of the optical device 2 may be described.

In the second state, the controller 3 may control the optical device 2 so that the second laser part 28 may emit the second laser beam LA2 and the first laser part 27 may not emit the first laser beam LA1. For example, in the second state, the first laser part 27 may not emit the first laser beam LA1, and the second laser part 28 may emit the second laser beam LA2.

In the second state, the mother substrate MS may be mounted on the stage 21 so that the first substrate SB1 may be supported on the stage 21 and the second substrate SB2 may be spaced apart from the stage 21. For example, the first substrate SB1 may be disposed on the stage 21, the display portions DP, the protection portions PTP, and the pad portions PDP may be disposed on the first substrate SB1, and the second substrate SB2 may be disposed on the display portions DP, the protection portions PTP, and the pad portions PDP.

In the second state, the fourth moving part 26 may adjust the height of the second laser part 28 so that the focus of the second laser beam LA2 may be formed inside the second substrate SB2. Accordingly, in a process where the second substrate SB2 is cut, damage to the display portions DP and the pad portions PDP may be reduced or minimized. In a state where the height of the second laser part 28 is adjusted, the first moving part 23 and/or the second moving part 24 may move the second laser part 28 in the first direction (e.g., the x-axis direction) and/or the second direction (e.g., the y-axis direction), respectively.

For example, as shown in FIGS. 10A and 10B, the first moving part 23 may move the second laser part 28 in the first direction (e.g., the x-axis direction). In such a process, as shown in FIG. 10C, the second substrate SB2 may be cut along the first direction (e.g., the x-axis direction).

However, as FIGS. 10A to 10C show an example of the second state of the optical device 2, the operation of the apparatus MD for manufacturing a display device is not limited thereto. For example, the second moving part 24 may move the second laser part 28 in the second direction (e.g., the y-axis direction), and the second substrate SB2 may also be cut along the second direction (e.g., the y-axis direction).

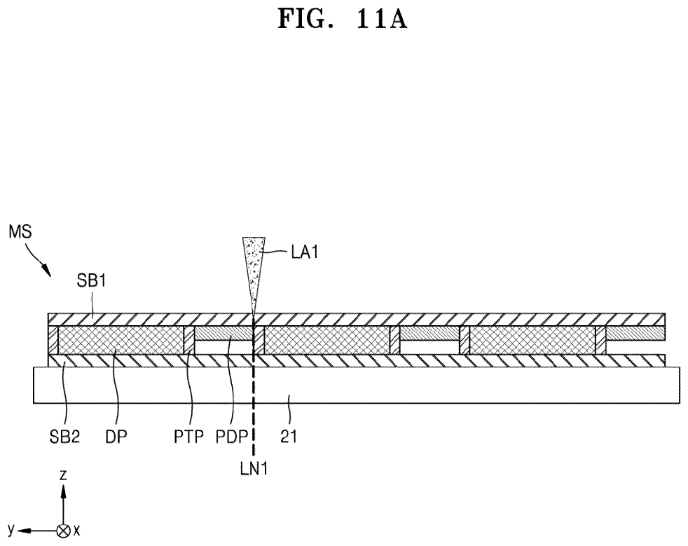

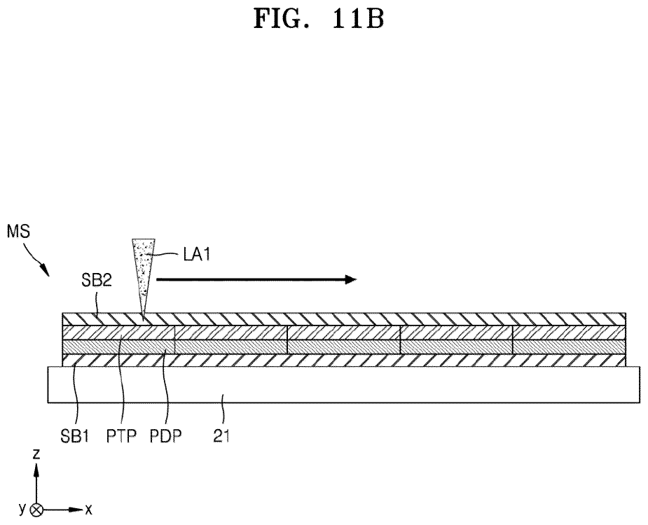

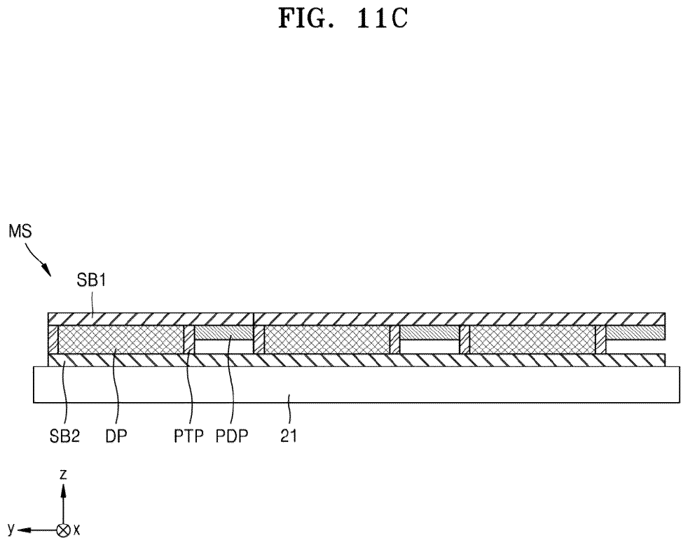

FIGS. 11A to 11C are schematic cross-sectional views each illustrating the display device 1 according to an embodiment.

FIGS. 11A and 11C are cross-sectional views taken along line II-II′ of FIG. 1, and FIG. 11 is a cross-sectional view taken along line III-III′ of FIG. 1.

Referring to FIGS. 8 and 11A to 11C, a third state of the optical device 2 may be described.

In the third state, the controller 3 may control the optical device 2 so that the first laser part 27 may emit the first laser beam LA1 and the second laser part 28 may not emit the second laser beam LA2. For example, in the third state, the first laser part 27 may emit the first laser beam LA1, and the second laser part 28 may not emit the second laser beam LA2.

In the third state, the mother substrate MS may be mounted on the stage 21 so that the second substrate SB2 may be supported on the stage 21 and the first substrate SB1 may be spaced apart from the stage 21. For example, the second substrate SB2 may be disposed on the stage 21, the display portions DP, the protection portions PTP, and the pad portions PDP may be disposed on the second substrate SB2, and the first substrate SB1 may be disposed on the display portions DP, the protection portions PTP, and the pad portions PDP.

In the third state, the third moving part 25 may adjust the height of the first laser part 27 so that the focus of the first laser beam LA1 may be formed inside the first substrate SB1. Accordingly, in a process where the first substrate SB1 is cut, damage to the display portions DP and the pad portions PDP may be reduced or minimized. In a state where the height of the first laser part 27 is adjusted, the first moving part 23 and/or the second laser part 28 may move the first laser part 27 in the first direction (e.g., the x-axis direction) and/or the second direction (e.g., the y-axis direction), respectively.

For example, as shown in FIGS. 11A and 11B, the first moving part 23 may move the first laser part 27 in the first direction (e.g., the x-axis direction). In such a process, as shown in FIG. 11C, the first substrate SB1 may be cut along the first direction (e.g., the x-axis direction).

However, as FIGS. 11A to 11C show an example of the third state of the optical device 2, the operation of the apparatus MD for manufacturing a display device is not limited thereto. For example, the second moving part 24 may move the first laser part 27 in the second direction (e.g., the y-axis direction), and the first substrate SB1 may also be cut along the second direction (e.g., the y-axis direction).

Referring to FIGS. 8, 9A to 9C, 10A to 10C, and 11A to 11C, the controller 3 may control the optical device 2 between the first state, the second state, and the third state. Accordingly, the apparatus MD for manufacturing a display device (or the optical device 2) may be switched between the first state, the second state, and the third state.

In case that the optical device 2 is switched between the first state and the third state or between the second state and the third state, the controller 3 may control the inversion part 29 to invert the mother substrate MS. For example, in case that the optical device 2 is switched between the first state and the third state or between the second state and the third state, the inversion part 29 may flip the mother substrate MS so that the top and bottom of the mother substrate MS may be inverted.

For example, for convenience of explanation, FIGS. 9A to 9C, 10A to 10C, and 11A to 11C show that the first substrate SB1 and/or the second substrate SB2 are immediately cut by the first laser part 27 and/or the second laser part 28, but an intermediate process may be added before the first substrate SB1 and/or the second substrate SB2 are cut. For example, after the first laser part 27 and/or the second laser part 28 half-cut the first substrate SB1 and/or the second substrate SB2, a process of breaking the first substrate SB1 and/or the second substrate SB2, which are half-cut, may be added. A known method may be used as the added process.

For example, first laser beams LA1 and/or second laser beams LA2, which are irradiated toward the mother substrate MS, may be provided. Accordingly, the mother substrate MS may be cut by the first laser beams LA1 and/or the second laser beams LA2 at the same time. The first laser beam LA1 and/or the second laser beam LA2 may be branched into laser beams by a separate optical branching device to be irradiated to the mother substrate MS. A known method may be used as the process of branching the first laser beam LA1 and/or the second laser beam LA2 into laser beams.

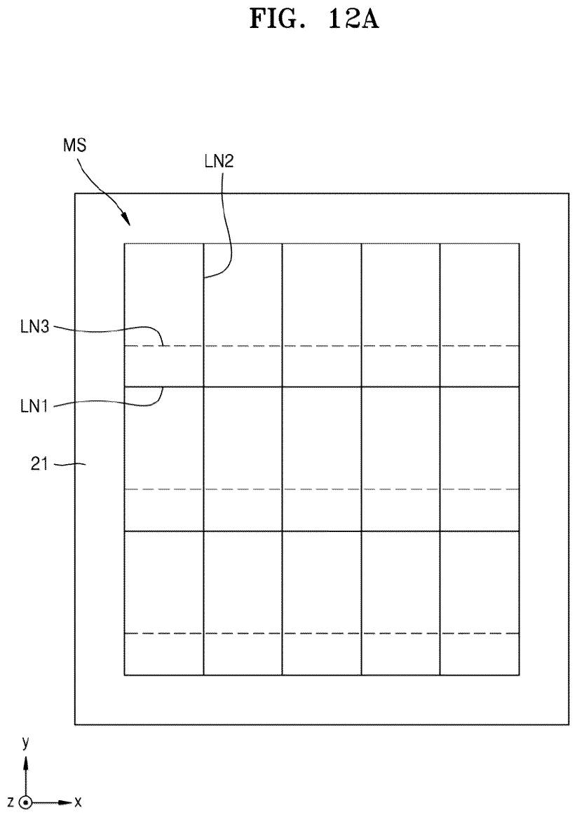

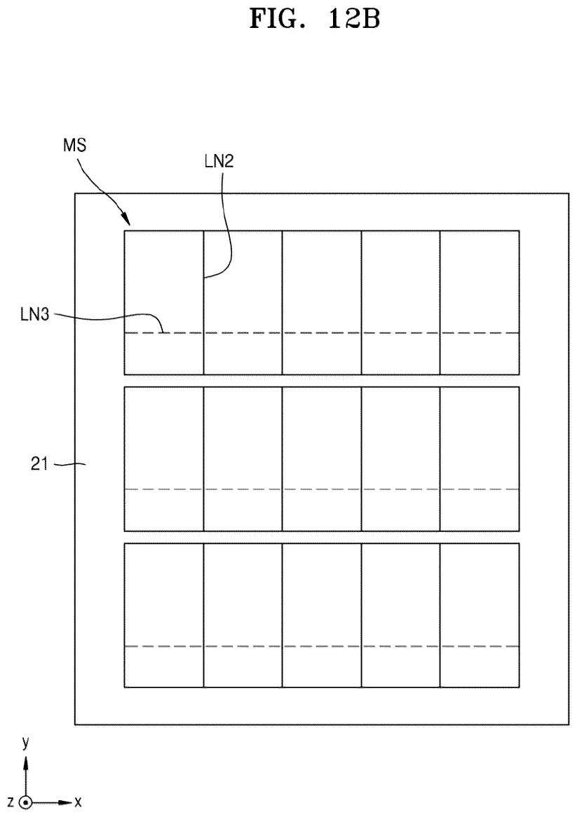

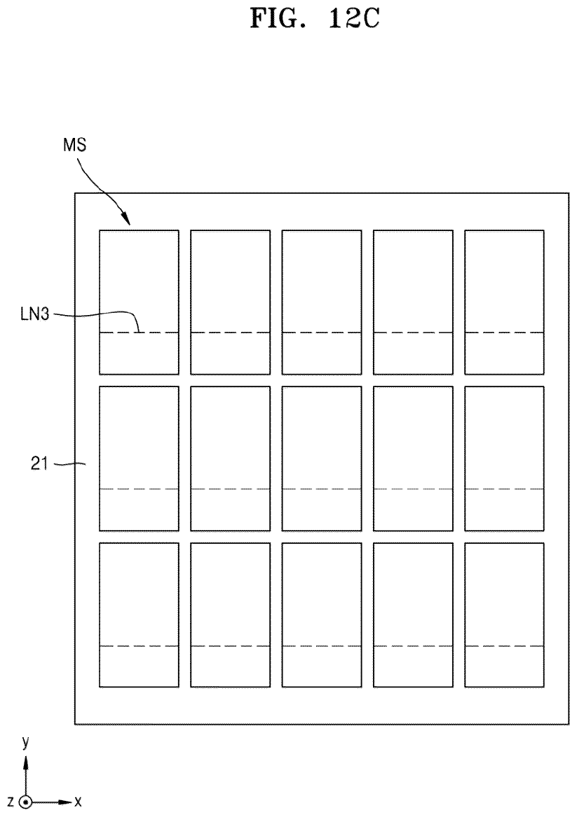

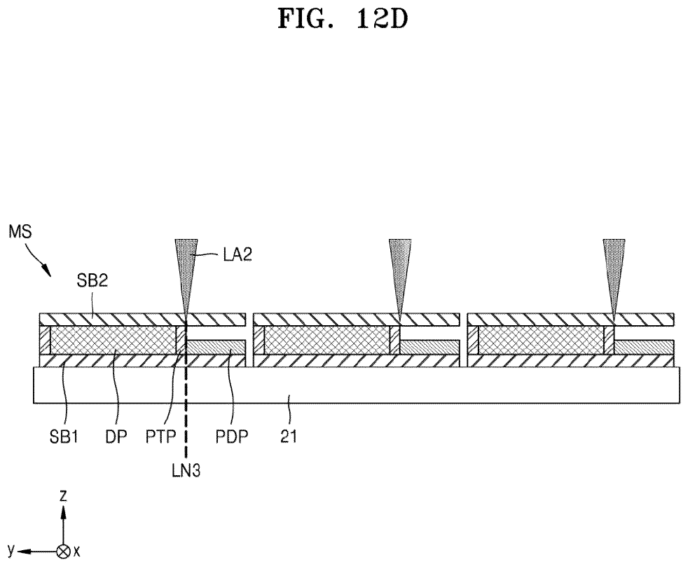

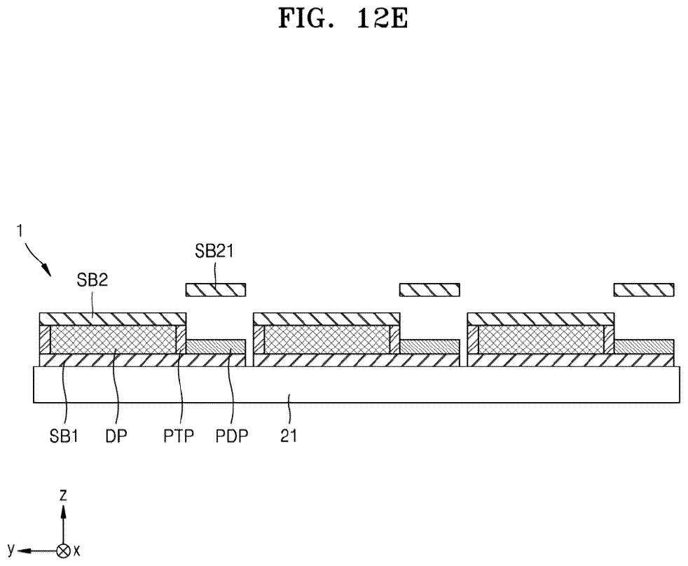

FIGS. 12A to 12C are schematic plan views each illustrating the mother substrate MS according to an embodiment, and FIGS. 12D and 12E are schematic cross-sectional views each illustrating the display device 1 according to an embodiment.

FIGS. 12D and 12E are cross-sectional views taken along line II-II′ of FIG. 1.

Referring to FIGS. 8 and 12A to 12E, the apparatus MD for manufacturing a display device may cut the mother substrate MS into display devices 1 along the cutting line CTL.

First, the mother substrate MS may be mounted on the stage 21. For example, the first substrate SB1 may be supported on the stage 21, and the second substrate SB2 may be spaced apart from the stage 21.

Referring to FIGS. 8 and 12A to 12C, the controller 3 may control the optical device 2 so that the first laser part 27 and the second laser part 28 may cut the mother substrate MS along the first line LN1 and the second line LN2 in the first state described above with reference to FIGS. 9A to 9C.

Referring to FIGS. 8, 12A, and 12B, in the first state, the first laser part 27 and the second laser part 28 may cut the mother substrate MS along the first line LN1. Referring to FIGS. 12B and 12C, in case that the mother substrate MS is cut along the first line LN1, the first laser part 27 and the second laser part 28 may cut the mother substrate MS along the second line LN2 in the first state. Accordingly, each of the first substrate SB1 and the second substrate SB2 may be cut along the first line LN1 and the second line LN2.

However, this is an example, and a sequence in which the mother substrate MS is cut is not limited to the first line LN1 and the second line LN2. For example, in the first state, after the first laser part 27 and the second laser part 28 cut the mother substrate MS along the second line LN2, the first laser part 27 and the second laser part 28 may also cut the mother substrate MS along the first line LN1 in the first state.

Referring to FIGS. 8, 12D, and 12E, the controller 3 may control the optical device 2 so that the second laser part 28 may cut the mother substrate MS along the third line LN3 in the second state as described above with reference to FIGS. 10A to 10C.

In case that the second laser part 28 cuts the mother substrate MS along the third line LN3 in the second state, the second substrate SB2 may be cut along the third line LN3. Accordingly, a scrap portion SB21, as a portion of the second substrate SB2, may be removed. The scrap portion SB21 may be a portion of the second substrate SB2, e.g., the portion overlapping the pad portion PDP. In case that the scrap portion SB21 is removed, the pad portion PDP may be exposed to the outside from the second substrate SB2. Thus, the mother substrate MS may be divided into the display devices 1.

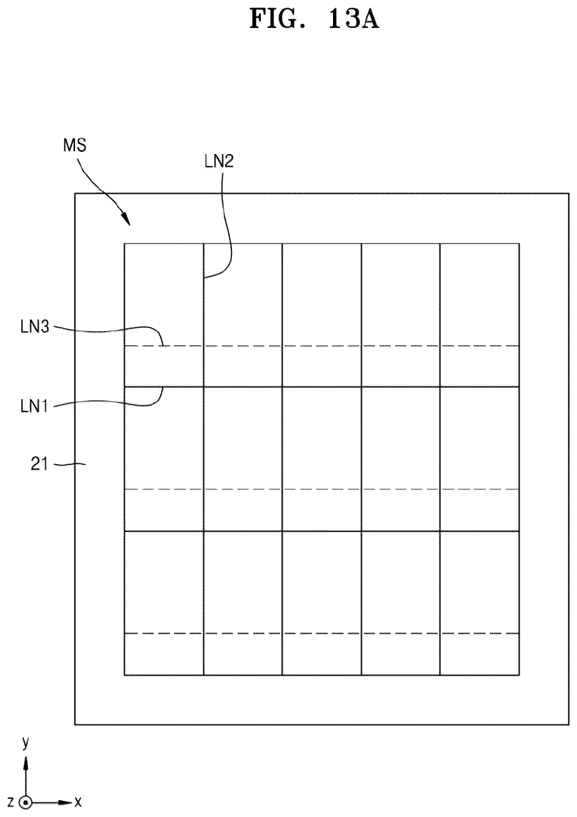

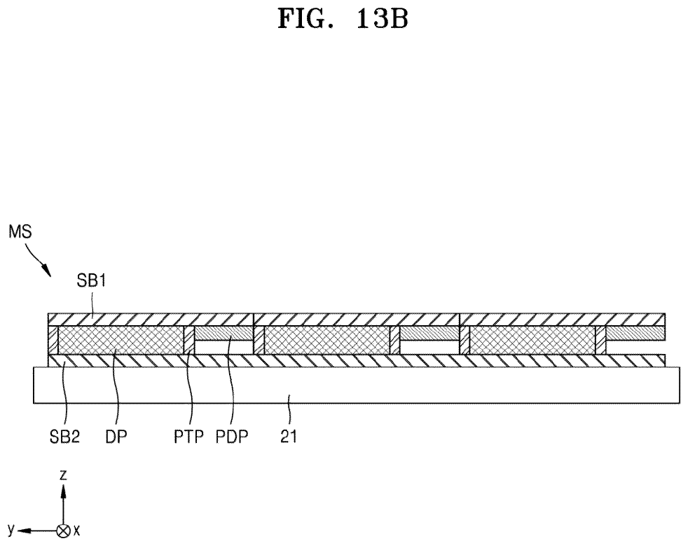

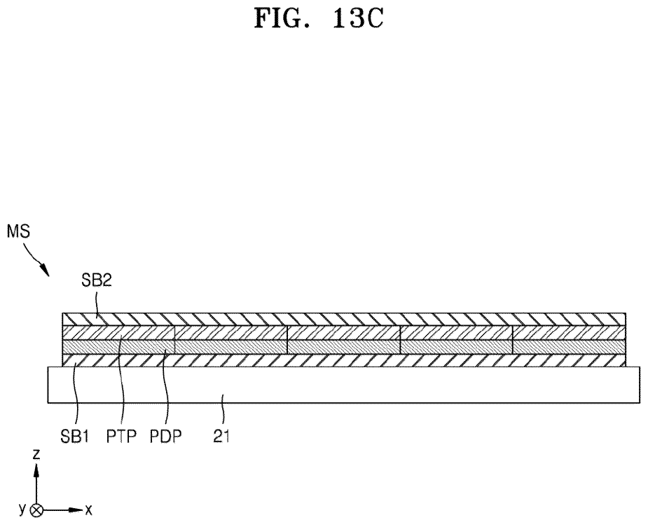

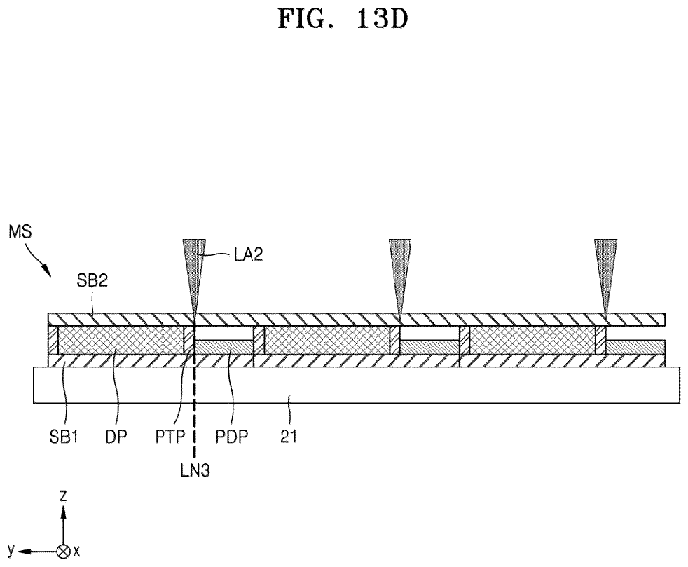

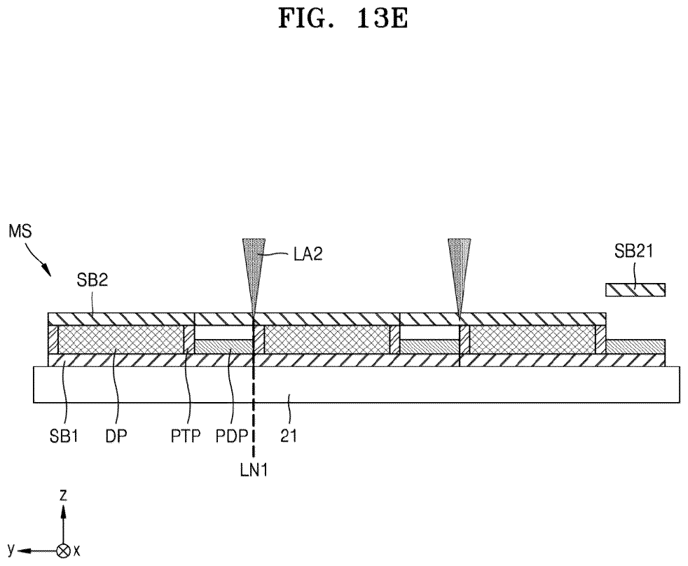

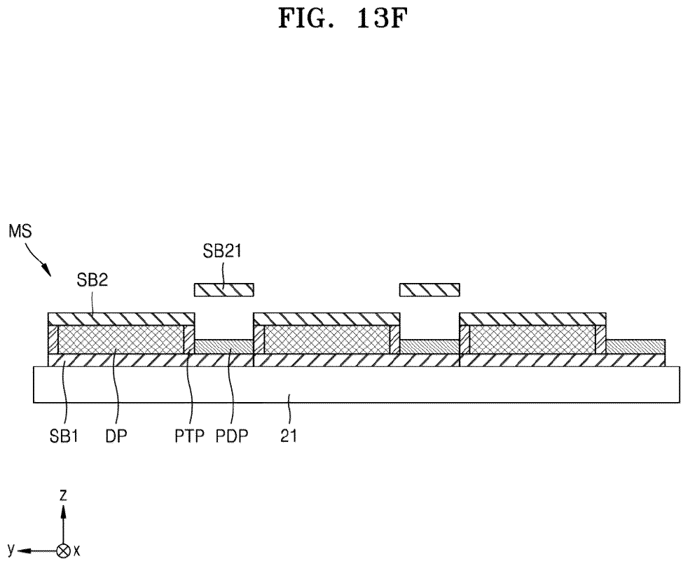

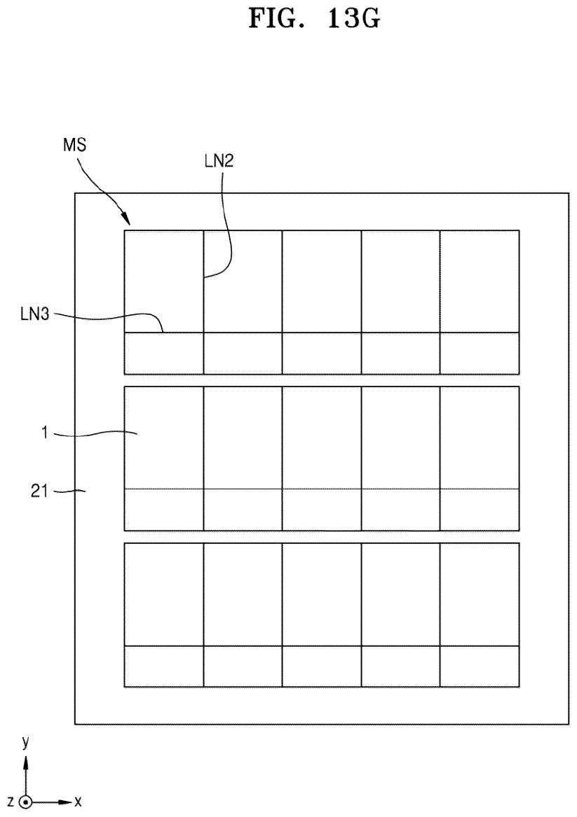

FIG. 13A is a schematic plan view of the mother substrate MS according to an embodiment, FIGS. 13B to 13F are schematic cross-sectional views each illustrating the display device 1 according to an embodiment, and FIG. 13G is a schematic plan view of the mother substrate MS according to an embodiment.

FIG. 13B is a cross-sectional view taken along line II-II′ of FIG. 1, FIG. 13C is a cross-sectional view taken along line III-III′ of FIG. 1, and FIGS. 13D to 13F are cross-sectional views each taken along line II-II′ of FIG. 1.

Referring to FIGS. 8 and 13A to 13G, the apparatus MD for manufacturing a display device may cut the mother substrate MS into the display devices 1 along the cutting line CTL.

For example, the mother substrate MS may be mounted on the stage 21. For example, the second substrate SB2 may be supported on the stage 21, and the first substrate SB1 may be spaced apart from the stage 21.

Referring to FIGS. 8 and 13A to 13C, the controller 3 may control the optical device 2 so that the first laser part 27 may cut the mother substrate MS along the first line LN1 and the second line LN2 in the third state as described above with reference to FIGS. 11A to 11C.

Referring to FIGS. 8, 13A, and 13B, in the third state, the first laser part 27 may cut the mother substrate MS along the first line LN1 and the second line LN2. Accordingly, the first substrate SB1 may be cut along the first line LN1 and the second line LN2.

The order (or sequence) in which the mother substrate MS is cut along the first line LN1 and the second line LN2 may vary. For example, after the first laser part 27 cuts the mother substrate MS along the first line LN1 in the third state, the first laser part 27 may cut the mother substrate MS along the second line LN2 in the third state. In another example, after the first laser part 27 cuts the mother substrate MS along the second line LN2 in the third state, the first laser part 27 may cut the mother substrate MS along the first line LN1.

Referring to FIGS. 8 and 13D to 13F, the inversion part 29 may invert the mother substrate MS. Accordingly, the first substrate SB1 may be supported on the stage 21, and the second substrate SB2 may be spaced apart from the stage 21.

The controller 3 may control the optical device 2 so that the second laser part 28 may sequentially cut the mother substrate MS along the third line LN3 and the first line LN1 in the second state as described above with reference to FIGS. 10A to 10C.

The second laser part 28 may sequentially cut the mother substrate MS along the third line LN3 and the first line LN1 in the second state. In case that the second substrate SB2 is sequentially cut along the third line LN3 and the first line LN1, the scrap portion SB21, as a portion of the second substrate SB2, may be removed. The scrap portion SB21 may be a portion of the second substrate SB2, the portion overlapping the pad portion PDP. In case that the scrap portion SB21 is removed, the pad portion PDP may be exposed to the outside from the second substrate SB2.

Referring to FIGS. 8 and 13G, the controller 3 may control the optical device 2 so that the second laser part 28 may cut the mother substrate MS along the second line LN2 in the second state. Accordingly, the second substrate SB2 may be cut along the second line LN2. For example, the second laser part 28 may sequentially cut the mother substrate MS along the third line LN3, the first line LN1, and the second line LN2. Thus, the mother substrate MS may be divided into the display devices 1.

According to embodiments, an apparatus for manufacturing a display device that reduces damage to the display device in a manufacturing process while having a simple manufacturing process.

Effects of the disclosure are not limited to the effects mentioned above, and other effects not mentioned will be clearly understood by one of ordinary in the art from the description of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display device, the apparatus cutting a mother substrate along a cutting line, wherein the mother substrate comprises a first substrate, a second substrate disposed on the first substrate, and a plurality of display portions and a plurality of pad portions, which are arranged between the first substrate and the second substrate, the apparatus comprising:
an optical device; and
a controller that controls the optical device, wherein
the optical device comprises:
a stage on which the mother substrate is mounted;
a first laser part disposed on the stage and that emits a first laser beam cutting the first substrate;
a second laser part disposed on the stage and that emits a second laser beam cutting the second substrate; and
a moving part that moves each of the first laser part and the second laser part;
the controller controls the optical device according to a first state, a second state, and a third state,
in the first state, the first laser part emits the first laser beam and the second laser part emits the second laser beam,
in the second state, the second laser part emits the second laser beam and the first laser part emits the first laser beam, and
in the third state, the first laser part emits the first laser beam and the second laser part does not emit the second laser beam.

2. The apparatus of claim 1, wherein
the mother substrate is divided into a plurality of cells arranged in a first direction and a second direction intersecting the first direction,
each of the plurality of cells comprises a display portion and a pad portion, and
the cutting line comprises:
a first line extending in the first direction and arranged between two adjacent cells;
a second line extending in the second direction and arranged between two adjacent cells; and
a third line extending in the first direction and arranged between a protection portion and the pad portion of a cell.

3. The apparatus of claim 2, wherein the controller controls the optical device so that the first laser part and the second laser part cut the mother substrate along the first line and the second line in the first state.

4. The apparatus of claim 3, wherein the controller controls the optical device so that the second laser part cuts the mother substrate along the third line in the second state.

5. The apparatus of claim 2, wherein the controller controls the optical device so that the first laser part cuts the mother substrate along the first line and the second line in the third state.

6. The apparatus of claim 5, wherein the controller controls the optical device so that the second laser part sequentially cuts the mother substrate along the third line, the first line, and the second line in the second state.

7. The apparatus of claim 1, wherein the moving part comprises:
a first moving part that moves each of the first laser part and the second laser part in a first direction;
a second moving part that moves each of the first laser part and the second laser part in a second direction intersecting the first direction;
a third moving part that moves the first laser part in a third direction intersecting the first direction and the second direction; and
a fourth moving part that moves the second laser part in the third direction.

8. The apparatus of claim 7, wherein the controller controls the third moving part and the fourth moving part so that the first laser part and the second laser part independently move in the third direction.

9. The apparatus of claim 1, wherein the first laser beam has a wavelength in a range of about 1.3 μm to about 2.5 μm and a pulse width in a range of about 1 ns to about 200 ns.

10. The apparatus of claim 1, wherein the second laser beam has a wavelength in a range of about 1.0 μm to about 2.5 μm and a pulse width in a range of about 300 fs to about 30 ps.

11. An apparatus for manufacturing a display device, the apparatus cutting a mother substrate along a cutting line, wherein the mother substrate comprises a first substrate, a second substrate disposed on the first substrate, and a plurality of display portions and a plurality of pad portions, which are arranged between the first substrate and the second substrate, the apparatus comprising:
a stage on which the mother substrate is mounted;
a first laser part disposed on the stage and that emits a first laser beam cutting the first substrate;
a second laser part disposed on the stage and that emits a second laser beam cutting the second substrate; and
a moving part that moves each of the first laser part and the second laser part, wherein
the apparatus is operated according to a first state, a second state, and a third state,
in the first state, the first laser part emits the first laser beam and the second laser part emits the second laser beam,
in the second state, the second laser part emits the second laser beam and the first laser part emits the first laser beam, and
in the third state, the first laser part emits the first laser beam and the second laser part does not emit the second laser beam.

12. The apparatus of claim 11, wherein
the mother substrate is divided into a plurality of cells arranged in a first direction and a second direction intersecting the first direction,
each of the plurality of cells comprises a display portion and a pad portion, and
the cutting line comprises:
a first line extending in the first direction and arranged between two adjacent cells;
a second line extending in the second direction and arranged between two adjacent cells; and
a third line extending in the first direction and arranged between a protection portion and the pad portion of a cell.

13. The apparatus of claim 12, wherein, in the first state, the first laser part and the second laser part cut the mother substrate along the first line and the second line.

14. The apparatus of claim 13, wherein, in the second state, the second laser part cuts the mother substrate along the third line.

15. The apparatus of claim 12, wherein, in the third state, the first laser part cuts the mother substrate along the first line and the second line.

16. The apparatus of claim 15, wherein, in the second state, the second laser part sequentially cuts the mother substrate along the third line, the first line, and the second line.

17. The apparatus of claim 11, wherein the moving part comprises:
a first moving part that moves each of the first laser part and the second laser part in a first direction;
a second moving part that moves each of the first laser part and the second laser part in a second direction intersecting the first direction;
a third moving part that moves the first laser part in a third direction intersecting the first direction and the second direction; and
a fourth moving part that moves the second laser part in the third direction.

18. The apparatus of claim 17, wherein the first laser part and the second laser part are moved independently in the third direction.

19. The apparatus of claim 11, wherein the first laser beam has a wavelength in a range of about 1.3 μm to about 2.5 μm and a pulse width in a range of about 1 ns to about 200 ns.

20. The apparatus of claim 11, wherein the second laser beam has a wavelength in a range of about 1.0 μm to about 2.5 μm and a pulse width in a range of about 300 fs to about 30 ps.
